(19) United States
(12) Patent Application Publication
(10) Pub. No.: US 2016/0225999 A1
(43) Pub. Date: Aug. 4, 2016

(54) ORGANIC-INORGANIC HYBRID PHOTOELECTRIC CONVERSION DEVICE INCLUDING CONDUCTIVE ORGANIC SEMICONDUCTOR COMPOUND AND METHOD FOR MANUFACTURING THE SAME

(71) Applicant: KOREA INSTITUTE OF SCIENCE AND TECHNOLOGY, Seoul (KR)

(72) Inventors: Hae Jung SON, Seoul (KR); Min Jae KO, Seoul (KR); Hong Gon KIM, Seoul (KR); Doh-Kwon LEE, Seoul (KR); Bong Soo KIM, Seoul (KR); Jin Young KIM, Seoul (KR); Sungmin PARK, Seoul (KR); Hyun Soo CHO, Seoul (KR)

(21) Appl. No.: 14/816,877

(22) Filed: Aug. 3, 2015

(30) Foreign Application Priority Data
Feb. 3, 2015 (KR) 10-2015-0016645

(51) Int. Cl. H01L 51/00; H01L 51/42

(52) U.S. Cl. CPC H01L 51/0059; H01L 51/005; H01L 51/4213; H01L 2031/0344

(57) ABSTRACT

Provided is an organic-inorganic hybrid photoelectric conversion device including a novel conductive organic semiconductor compound including paracyclophene and an organic-inorganic perovskite compound. A hole transport layer containing the conductive organic semiconductor compound including paracyclophene and a light absorbing layer are bound well organically with each other. Thus, it is possible to accomplish high photoelectric conversion efficiency. In addition, the organic-inorganic hybrid photoelectric conversion device is formed of a solid phase and has high stability, uses inexpensive materials, is obtained by a simple and easy process at low processing cost, and thus allows mass production with high cost efficiency, resulting in high commercial viability.

### CROSS-REFERENCE TO RELATED APPLICATIONS

This application claims priority under 35 U.S.C. §119 to Korean Patent Application No. 10-2015-0016645 filed on Feb. 3, 2015 in the Korean Intellectual Property Office, the disclosure of which is incorporated herein by reference in its entirety.

### TECHNICAL FIELD

The following disclosure relates to an organic-inorganic photoelectric conversion device including a novel conductive organic semiconductor compound including paracyclophene. More particularly, the following disclosure relates to an organic-inorganic photoelectric conversion device including a novel p-type organic semiconductor compound and an organic-inorganic hybrid perovskite compound, and a method for manufacturing the same.

### BACKGROUND

A solar cell or photovoltaic cell means a device with which solar energy can be converted into electric energy, generates current-voltage by using a photovoltaic effect in which a photosensitive material absorbs light to produce electrons and holes, and allows solar energy as a source of all types of energy in the earth to be utilized in life without pollution.

The initial semiconductor-based solar cells using an n-p diode of inorganic compound semiconductor, such as silicon or gallium arsenide (GaAs), have a problem in that the cost required for a silicon material and wafer occupies a high proportion of 40% or more based on the total manufacturing cost.

To solve the above-mentioned problem, thin film amorphous silicon-, CIGS- or CZTS-based solar cells or solar cells having an organic-inorganic thin film structure using a dye or polymer have been developed.

Particularly, intensive studies about silicon material-free organic-inorganic hybrid solar cells or dye-sensitized solar cells were started.

Unlike silicon solar cells, organic-inorganic hybrid solar cells are photoelectrochemical solar cells essentially including a photosensitive dye molecule capable of absorbing visible rays to generate electron-hole pairs and a transition metal oxide transporting the generated electrons. Such organic-inorganic hybrid solar cells are advantageous in that they provide high efficiency at low cost and are manufactured to have transparency and flexibility. However, since such solar cells use a liquid electrolyte, they have a problem of leakage when the binding between electrodes is not complete. Meanwhile, when using a gel-type electrolyte, the problem of leakage may be solved but another problem occurs in that the movement of oxidation-reduction species becomes slow.

To solve the above-mentioned problems of organic-inorganic hybrid solar cells, solar cells using a solid electrolyte have been developed. However, in this case, the charge transporting rate is significantly slower compared to the solar cells using a liquid electrolyte and gel-type electrolyte, and thus the photoelectric conversion efficiency is low (Non-patent Documents 1 and 2).

To solve the above-mentioned problems, perovskite solar cells have been developed through the use of perovskite having a light absorption coefficient about 10 times higher than the light absorption coefficient of a conventional dye. For example, in 2009, Miyajaka and coworkers prepared CH₃NH₃PbI₃ and CH₃NH₃PbBr₃, which still had a low efficiency of 3.81% and 3.13%, respectively (Non-Patent Document 3).

As described above, although various materials for the electrolyte and dye in an organic-inorganic hybrid cell have been suggested, they are limited in efficiency. Therefore, there is a need for developing a novel electron transporting material or hole transporting material.

### REFERENCES

### Non-Patent Documents

Non-Patent Document 1. Bach, V. et al. Nature 395, 583-585 1998
Non-Patent Document 2. Henry Snaith, “Charge transport in mesoscopic hybrid solar cells”, SPIE, (2008)
Non-Patent Document 3. Akihiro Kojima. et al, J. Am. Chem. Soc., 131, 6050-6051 (2009)

### SUMMARY

To solve the above-described problems, an embodiment of the present disclosure is directed to providing an organic-inorganic photoelectric conversion device having excellent photoelectric conversion efficiency.

Another embodiment of the present disclosure is directed to providing a method for manufacturing the organic-inorganic hybrid photoelectric conversion device in a large scale.

Still another object of the present disclosure is directed to providing a method for preparing a conductive organic compound for use in the organic-inorganic hybrid photoelectric conversion device in a large scale.

To accomplish the above-mentioned objects, the present disclosure provides an organic-inorganic hybrid photoelectric conversion device, including a first electrode, a second electrode opposite to the first electrode, and an electron transport layer, light-absorbing material and a hole transport layer disposed between the first electrode and the second electrode, wherein the light-absorbing material includes an organic-inorganic hybrid perovskite compound, and the hole transport layer includes a conductive organic semiconductor compound represented by the following Chemical Formula I or Formula II:

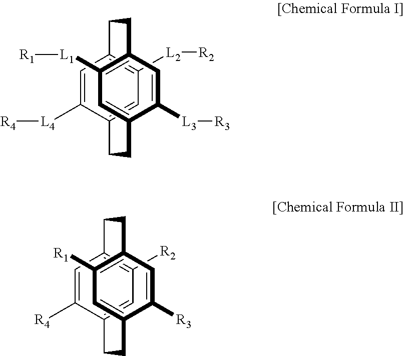

In Chemical Formula I or Chemical Formula II,

L₁, L₂, L₃ and L₄ are the same or different, and each independently represents any one selected from the group consisting of a substituted or non-substituted C5-C50 aryl group and a substituted or non-substituted C2-C50 heteroaryl group containing at least one of S, N, O, P and Si; and

R₁, R₂, R₃ and R₄ are the same or different, and each independently represents any one selected from the following Structural Formula 1:

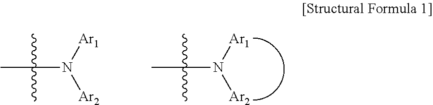

wherein Ar₁ and Ar₂ are the same or different, and each independently represents any one selected from the group consisting of a substituted or non-substituted C5-C50 aryl group and a substituted or non-substituted C2-C50 heteroaryl group containing at least one of S, N, O, P and Si; and

Ar₁ and Ar₂ may be linked to each other through a bonding.

Additionally, in the above Chemical Formula I or Chemical Formula II, each of L₁, L₂, L₃ and L₄ may be any one selected from the following Structural Formula 2:

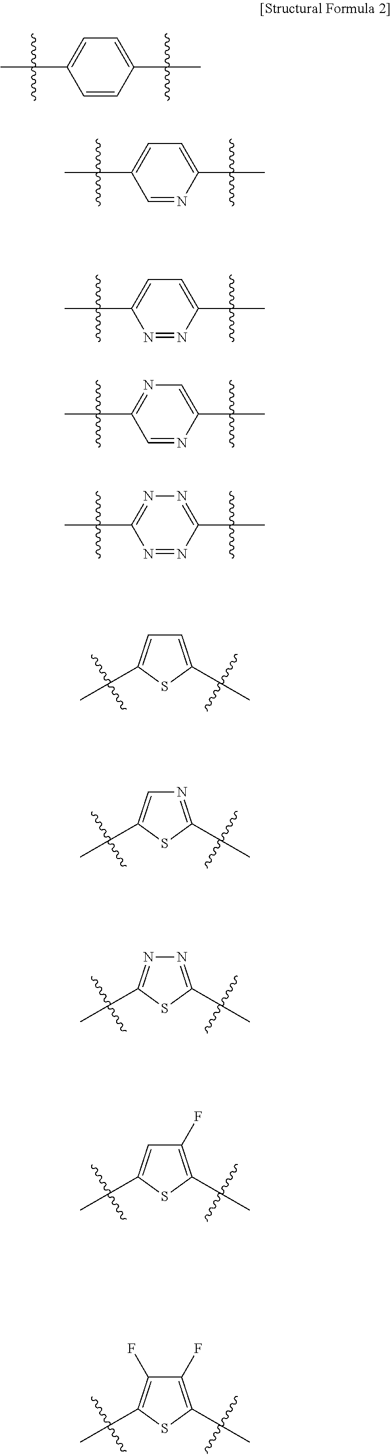

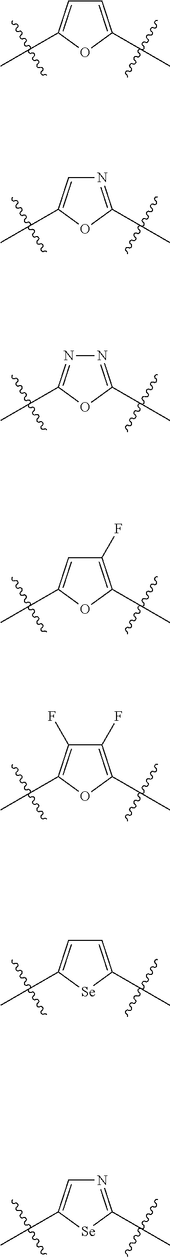

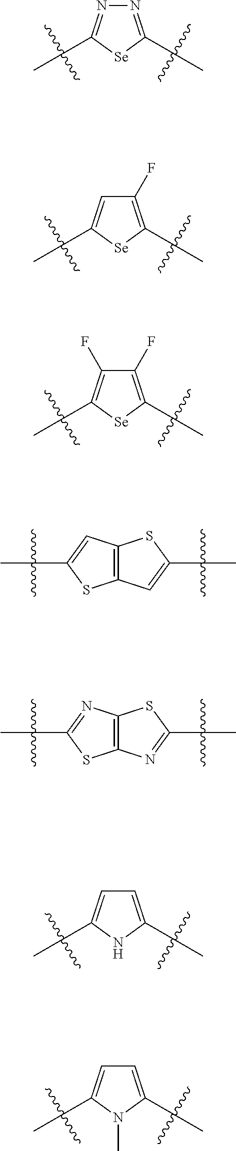

Further, in the above Chemical Formula I or Chemical Formula II, each of Ar₁ and Ar₂ may be any one selected from the following Structural Formula 3:

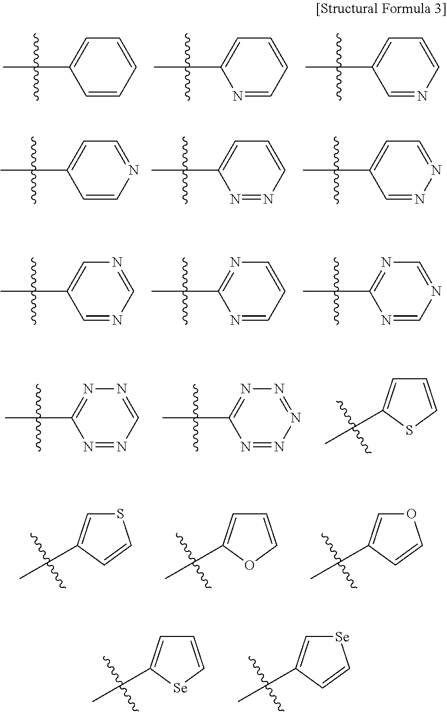

The above Structural Formula 3 may be substituted with any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

In addition, the conductive organic semiconductor compound represented by the above Chemical Formula 1 may be a conductive organic semiconductor compound represented by the following Chemical Formula III:

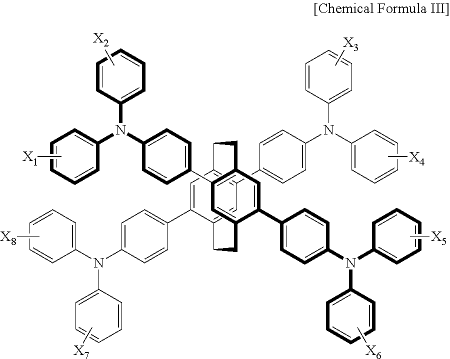

In Chemical Formula III,

X₁, X₂, X₃, X₄, X₅, X₆, X₇ and X₈ are the same or different, and each is independently selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

The conductive organic semiconductor compound represented by the above Chemical Formula II may be a conductive organic semiconductor compound represented by the following Chemical Formula IV:

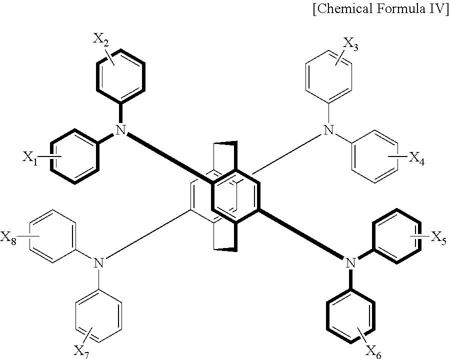

In Chemical Formula IV,

X₁, X₂, X₃, X₄, X₅, X₆, X₇ and X₈ are the same or different, and each independently represents any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

The conductive organic semiconductor compound may have an electron mobility of 1×10⁻⁶ cm²/V·s or higher.

The conductive organic semiconductor compound may have a band gap of 1.0-4.0 eV.

The hole transport layer may further include a sulfonyl group-containing imide lithium salt.

The sulfonyl group-containing imide lithium salt may be at least one selected from the group consisting of lithium bis(trifluoromethane sulfonyl)imide (LITFSI), lithium bis(perfluroethylsulfonyl) imide (BETI), lithium bis[(perefluoroalkyl)sulfonyl]imide and lithium poly[4,4′-(hexafluoroisopropylidene)diphenoxy]sulfonyl imide (LiPHFIPSI).

In another aspect, the present disclosure provides a method for manufacturing an organic-inorganic hybrid photoelectric conversion device, including the steps of:

I) forming an electron transport layer on a first electrode;

II) forming a light-absorbing material including an organic-inorganic hybrid perovskite compound on the electron transport layer;

III) applying a solution containing a conductive organic semiconductor compound represented by the above Chemical Formula I or Chemical Formula II onto the light-absorbing material, followed by drying, to form a hole transport layer; and

IV) forming a second electrode on the hole transport layer.

Step III) may be carried out by applying a solution containing at least one conductive organic semiconductor compound selected from the group consisting of conductive organic semiconductor compounds represented by Chemical Formula I or Chemical Formula II through any one process selected from the group consisting of a vacuum deposition process, screen printing process, printing process, spin coating process, dipping process and an ink spraying process.

In step III), the solution containing a conductive organic semiconductor compound represented by Chemical Formula I or Chemical Formula II and applied onto the light-absorbing material may further include a sulfonyl group-containing imide lithium salt.

The sulfonyl group-containing imide lithium salt may be at least one selected from the group consisting of lithium bis(trifluoromethanesulfonyl) imide (LITFSI), lithium bis(perfluroethylsulfonyl) imide (BETI), lithium bis[(perefluoroalkyl)sulfonyl]imide and lithium poly[4,4′-(hexafluoroisopropylidene)diphenoxy]sulfonyl imide (LiPHFIPSI).

In still another aspect, the present disclosure provides a method for preparing a conductive organic semiconductor compound, including the steps of:

i) dissolving a compound represented by the following Chemical Formula VII and a compound represented by the following Chemical Formula VIII into a solvent to provide a mixed solution;

ii) adding a palladium catalyst to the mixed solution and carrying out a reaction of the compound represented by the following Chemical Formula VII with the compound represented by the following Chemical Formula VIII to obtain a conductive organic semiconductor compound represented by the following Chemical Formula I:

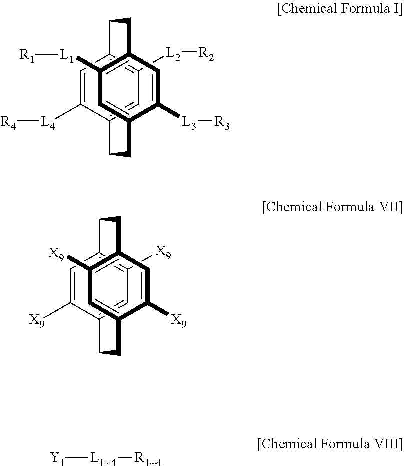

In Chemical Formula VII, X₉ represents a halide such as Cl, Br or I.

In Chemical Formula I and Chemical Formula VIII,

Y₁ is any one selected from BO₂R₅R₆ and SnR₇R₈R₉, R₅, R₆, R₇, R₈ and R₉ are the same or different, and each represents hydrogen or a C1-C8 alkyl group, wherein R₅ and R₆ are linked to each other through a bonding.

L₁₋₄ (L₁, L₂, L₃ and L₄) are the same or different, and each is independently selected from the group consisting of a substituted or non-substituted C5-C50 aryl group and substituted or non-substituted C2-C50 heteroaryl group containing at least one of S, N, O, P and Si.

Each of R₁₋₄ (R₁, R₂, R₃ and R₄) is any one selected from the following Structural Formula 1:

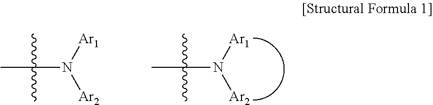

wherein Ar₁ and Ar₂ are the same or different, and each independently represents any one selected from the group consisting of a substituted or non-substituted C5-C50 aryl group and a substituted or non-substituted C2-C50 heteroaryl group containing at least one of S, N, O, P and Si; and

Ar₁ and Ar₂ may be linked to each other through a bonding.

In the above Chemical Formula VIII, each of L₁₋₄ (L₁, L₂, L₃ and L₄) may be any one selected from the following Structural Formula 2:

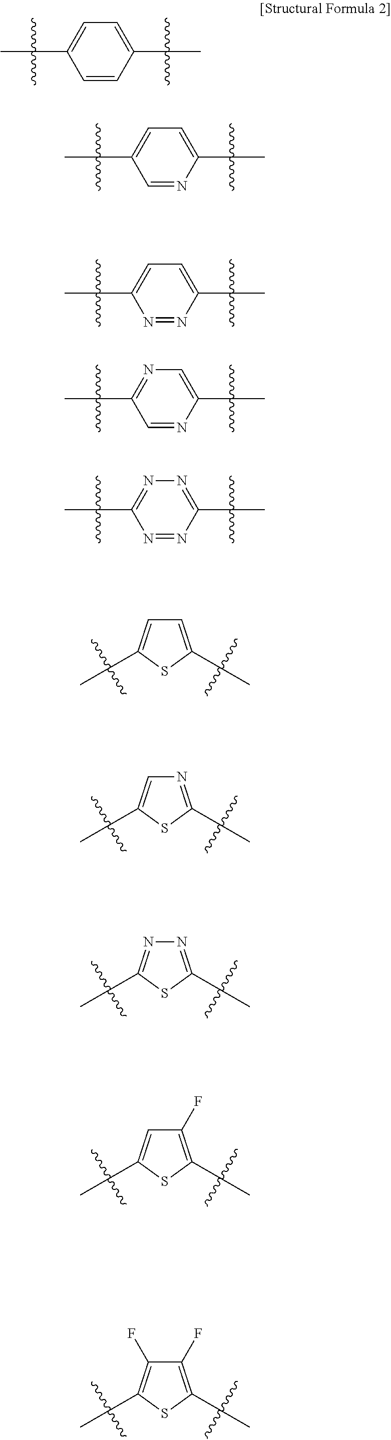

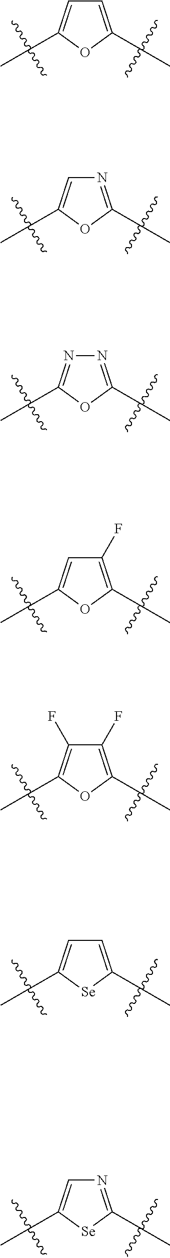

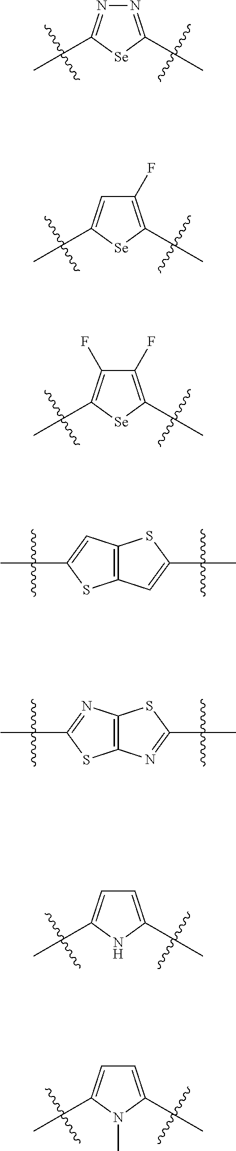

In Structural Formula 1, Ar₁ and Ar₂ are the same or different and each may be any one selected from the following Structural Formula 3:

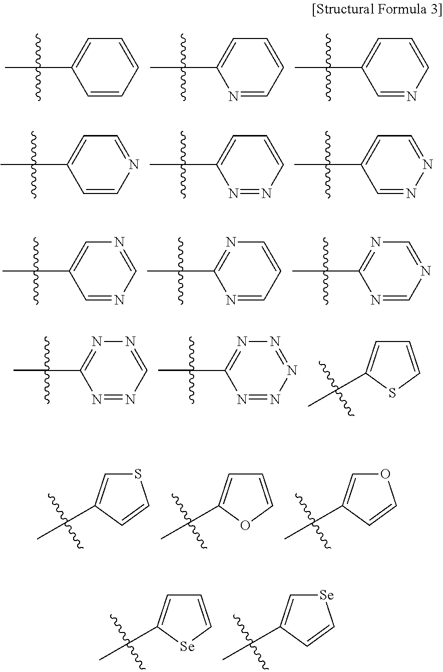

The above Structural Formula 3 may be substituted with any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

The mixing ratio of the compound represented by Chemical Formula VII to the compound represented by Chemical Formula VIII may be 1:0.5-10 on the molar basis.

In yet another aspect, there is provided a method for preparing a conductive organic semiconductor compound, including the following steps of:

i) dissolving a compound represented by the following Chemical Formula VII and a compound represented by the following Chemical Formula IX into a solvent to provide a mixed solution;

ii) adding a palladium catalyst to the mixed solution and carrying out a reaction of the compound represented by the following Chemical Formula VII with the compound represented by the following Chemical Formula IX to obtain a conductive organic semiconductor compound represented by the following Chemical Formula II:

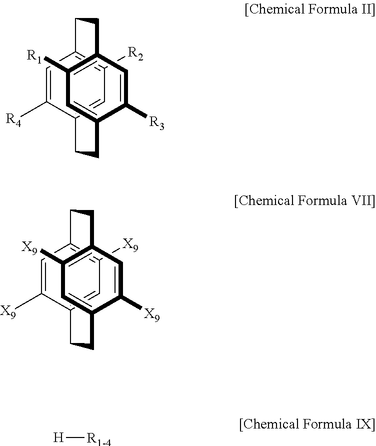

In Chemical Formula VII, X₉ represents a halide such as Cl, Br or I.

In Chemical Formula II and Chemical Formula IX,

R₁₋₄ is any one selected from the following Structural Formula 1:

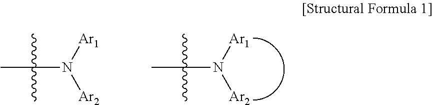

wherein Ar₁ and Ar₂ are the same or different, and each independently represents any one selected from the group consisting of a substituted or non-substituted C5-C50 aryl group and a substituted or non-substituted C2-C50 heteroaryl group containing at least one of S, N, O, P and Si; and

Ar₁ and Ar₂ may be linked to each other through a bonding.

In Structural Formula 1, Ar₁ and Ar₂ are the same or different and each may be any one selected from the following Structural Formula 3:

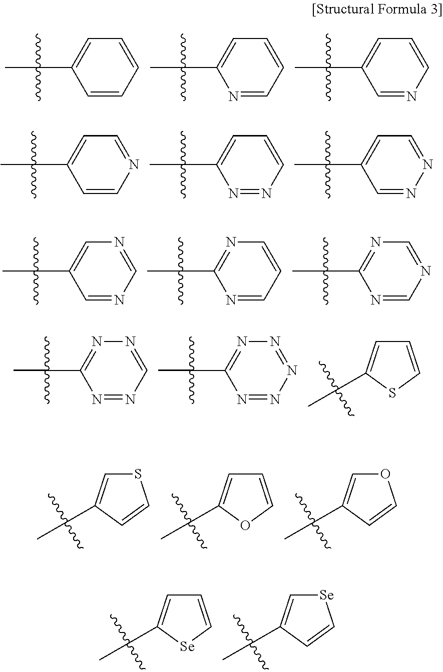

The above Structural Formula 3 may be substituted with any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

The mixing ratio of the compound represented by Chemical Formula VII to the compound represented by Chemical Formula IX may be 1:0.5-10 on the molar basis.

The present disclosure relates to an organic-inorganic hybrid photoelectric conversion device which includes a novel conductive organic semiconductor compound including paracyclophene and an organic-inorganic hybrid perovskite compound. When using the conductive organic semiconductor compound including paracyclophene as a hole transport layer, the hole transport layer and the light absorbing layer are organically bound well with each other. Therefore, it is possible to obtain high photoelectric conversion efficiency.

In addition, the organic-inorganic hybrid photoelectric conversion device is formed of a solid phase to provide excellent stability, and uses low-cost materials to provide high cost efficiency.

Further, the conductive organic semiconductor compound used in the organic-inorganic hybrid photoelectric conversion device is prepared through a simple and easy process and is amenable to mass production at low cost. Therefore, when using the conductive organic semiconductor compound for organic-inorganic hybrid photoelectric conversion devices, it is possible to reduce the cost required for processing the organic-inorganic hybrid photoelectric conversion devices and to provide them with high commercial viability.

### BRIEF DESCRIPTION OF THE DRAWINGS

FIG. 1 is a sectional view illustrating the organic-inorganic hybrid photoelectric conversion device according to an embodiment.

FIG. 2 is an absorbance graph of the compound (Chemical Formula V) obtained from Preparation Example 1.

FIG. 3 is a cyclic voltammetry graph of the compound (Chemical Formula V) obtained from Preparation Example 1.

FIG. 4 is a graph illustrating the current-voltage characteristics of the organic-inorganic hybrid photoelectric conversion device obtained from Example 1.

### DETAILED DESCRIPTION OF EMBODIMENTS

Hereinafter, the organic-inorganic hybrid photoelectric conversion device according to an embodiment of the present disclosure and an organic-inorganic hybrid solar cell using the same will be explained in detail.

In one aspect, there is provided an organic-inorganic hybrid photoelectric conversion device, including a first electrode, a second electrode opposite to the first electrode, and an electron transport layer, light-absorbing material and a hole transport layer disposed between the first electrode and the second electrode, wherein the light-absorbing material includes an organic-inorganic hybrid perovskite compound, and the hole transport layer includes a paracyclophene structure.

In other words, the organic-inorganic hybrid photoelectric device according to the present disclosure uses not only a compound having a perovskite structure as a light absorbing material that absorbs the solar light to generate exitons but also an electron transport layer containing an n-type semiconductor compound or metal oxide, in addition to the hole transport layer of a conductive organic semiconductor compound containing a paracyclophene structure. Thus, it is possible to accomplish high durability and high conversion efficiency.

In addition, when using the conductive organic semiconductor compound containing a paracyclophene structure as a hole transport layer according to the present disclosure, the compound containing a paracyclophene structure is one having a conjugated surface formed by π-π interaction and has a rigid and highly dense arrangement, and thus shows excellent electron transportability and is provided with an electron blocking function by which the electrons generated from the light absorbing material are prevented from flowing out toward the second electrode. This makes the compound containing a paracyclophene structure useful as a hole transport layer. By virtue of the electron blocking function, it is possible to prevent electric current quenching caused by recombination upon the movement of photoelectric current, thereby improving the photoelectric conversion efficiency. In addition, the compound containing a paracyclophene structure is obtained through a simple and easy process, thereby reducing the cost required for preparing the same.

FIG. 1 is a sectional view illustrating an embodiment of the organic-inorganic hybrid photoelectric conversion device.

Referring to FIG. 1, the organic-inorganic hybrid photoelectric conversion device according to the present disclosure may include a structure having a first electrode 110, electron transport layer 120, light absorbing material 130, hole transport layer 140 and a second electrode 150, stacked successively.

The first electrode 110 may be a transparent substrate having a transparent electrode, and any transparent electrode and transparent substrate may be used as long as they are used conventionally in the field of organic-inorganic hybrid photoelectric conversion devices or organic-inorganic hybrid solar cells. For example, the transparent electrode may include fluorine doped tin oxide (FTO) or indium doped tin oxide (ITO). Herein, the transparent substrate may include glass.

The electron transport layer 120 serves to provide a path through which electrons move smoothly, and may include an n-type semiconductor compound or metal oxide.

When the electron transport layer 120 includes a metal oxide, it may include a plurality of metal oxide particles. In this case, the electron transport layer 120 may form a porous structure having open pores. The light absorbing material 130 may be provided in such a manner that it may be adjacent to the metal oxide particles present inside the pores of the porous electron transport layer 120.

The metal oxide particles contained in the electron transport layer 120 may be any conventional metal oxide particles with no particular limitation. Preferably, the metal oxide particles may be at least one type of particles selected from the group consisting of Ti oxide, In oxide, Zn oxide, Sn oxide, W oxide, Nb oxide, Mo oxide, Mg oxide, Zr oxide, Sr oxide, Yr oxide, La oxide, V oxide, Al oxide, Sc oxide, Sm oxide, Ga oxide, SrTi oxide and a combination thereof.

In addition, when the electron transport layer 120 includes an n-type semiconductor compound, any n-type semiconductor compound may be used with no particular limitation. For example, the n-type semiconductor compound may include fullerene, octaazaporpyrin, polymeric compounds having aromatic carboxylic anhydride or imide compound as a skeleton, or the like. It is most preferable to use a fullerene derivative having improved solubility. Also in this case, a porous structure may be formed.

When the electron transport layer 120 has a porous structure, it has an increased specific surface area to facilitate transport of electrons and provides a contact surface with a large amount of light absorbing materials to increase the photosensitive region. Therefore, it is possible for the exitons to be transferred to the adjacent metal oxide particles before quenching, thereby facilitating electron-hole dissociation.

The electron transport layer 120 may have a thickness of 0.1-5 μm. When the electron transport layer 120 has a thickness less than 0.1 μm, the contact surface with the light absorbing material 130 is decreased, resulting in degradation of efficiency. When the electron transport layer 120 has a thickness larger than 5 μm, the flow distance of photoelectric current is increased, resulting in degradation of efficiency.

The electron transport layer 120 preferably has a hole blocking effect by which the holes are prevented from moving toward the first electrode 110. To accomplish this, a metal oxide thin film may be further provided between the electron transport layer 120 and the first electrode 110.

The light absorbing material 130 is not a dye that absorbs the light to generate exitons but an organic-inorganic hybrid perovskite compound (also referred to as ‘organic-inorganic perovskite’ hereinafter).

More particularly, there is no particular limitation in organic-inorganic perovskite compound, as long as it is a compound having a perovskite structure in which an inorganic material and an organic material are combined and bound to each other. Most preferably, it may be an organic-inorganic perovskite compound represented by the formula of RMX₃. Herein, M may be Pt⁺ or Sn⁺, X may be any one selected from the halogen anions including F⁻, Cl⁻, Br and I⁻, and R may be any one selected from the cations including CH₃NH₃⁺, C₂H₅NH₃⁺, Cs⁺ and HC(NH₂)NH₂⁺.

The light absorbing material 130 may be disposed between the electron transport layer 120 and the hole transport layer 140 so that it may be in interfacial contact while forming a heterojunction interface between the electron transport layer 120 and the hole transport layer 140.

Since such a light absorbing material 130 having an organic-inorganic perovskite structure is obtained by a simple process, it is expected that such a light absorbing material provides high cost efficiency. However, there has been a problem in that such a light absorbing material undergoes decomposition of photosensitizer due to a liquid electrolyte, resulting in poor durability.

However, the above-mentioned problem can be solved by improving the stability (i.e., durability) of the light absorbing material 130 through the electron transport layer 120 including a conductive organic semiconductor compound, the perovskite-structured light absorbing material 130 applied thereon, and a hole transport layer 140 formed subsequently. In this manner, it is possible to increase photoelectric conversion efficiency.

Herein, the hole transport layer 140 includes a conductive organic semiconductor compound represented by the following Chemical Formula I or Chemical Formula II. Such a compound having a paracyclophene structure is one having a conjugated surface formed by π-π interaction and has a rigid and highly dense arrangement, and thus shows excellent electron transportability and is provided with an electron blocking function by which the electrons generated from the light absorbing material 130 are prevented from flowing out toward the second electrode 150. This makes the compound useful as a hole transport layer 140. By virtue of the electron blocking function, it is possible to prevent current quenching caused by recombination upon movement of photoelectric current, thereby improving photoelectric conversion efficiency.

Moreover, the compound having a paracyclophene structure is prepared with ease and the cost required for preparing the conductive organic semiconductor compound is significantly lower compared to the conventional hole transport materials, such as 2,2,7,7-tetrakis(N,N-p-dimethoxyphenylamino)-9,9′-spirobyfluorene (Spiro-OMeTAD), 2,7-bis(N,N-(4-dimethoxyphenyl)amino)-9,9′-spirobifluorene (Spiro-MeoTPD) and 2,2′-bis(N,N-(4-dimethoxyphenyl)amino)-9,9′-spirobifluorene (2,2-MeO-spiro-TPD). Thus, it is possible to produce organic-inorganic hybrid photoelectric conversion devices at low cost in a large scale.

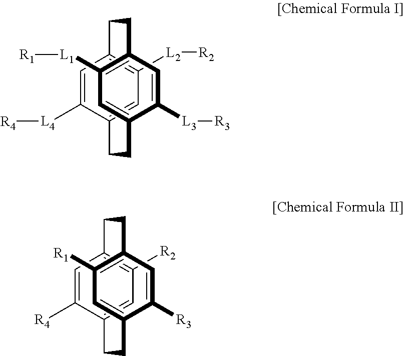

In Chemical Formula I or Chemical Formula II,

L₁, L₂, L₃ and L₄ are the same or different, and each independently represents any one selected from the group consisting of a substituted or non-substituted C5-C50 aryl group and a substituted or non-substituted C2-C50 heteroaryl group containing at least one of S, N, O, P and Si; and

R₁, R₂, R₃ and R₄ are the same or different, and each independently represents any one selected from the following Structural Formula 1:

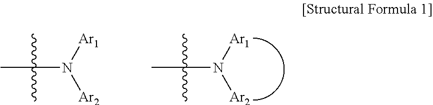

wherein Ar₁ and Ar₂ are the same or different, and each independently represents any one selected from the group consisting of a substituted or non-substituted C5-C50 aryl group and a substituted or non-substituted C2-C50 heteroaryl group containing at least one of S, N, O, P and Si; and

Ar₁ and Ar₂ may be linked to each other through a bonding.

Additionally, in the above Chemical Formula I or Chemical Formula II, each of L₁, L₂, L₃ and L₄ may be any one selected from the following Structural Formula 2:

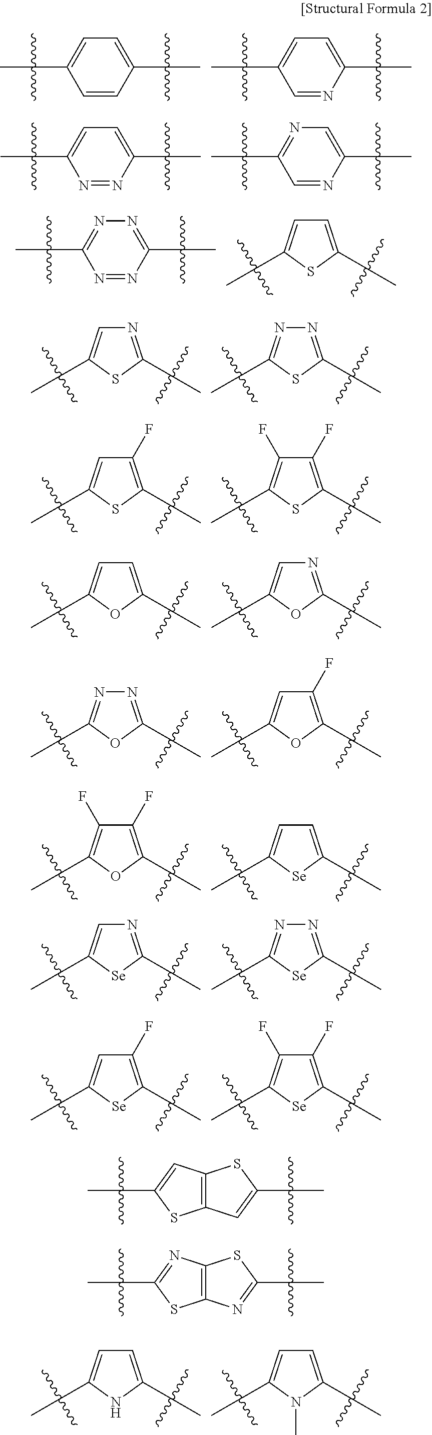

Further, in the above Chemical Formula I or Chemical Formula II, each of Ar₁ and Ar₂ may be any one selected from the following Structural Formula 3:

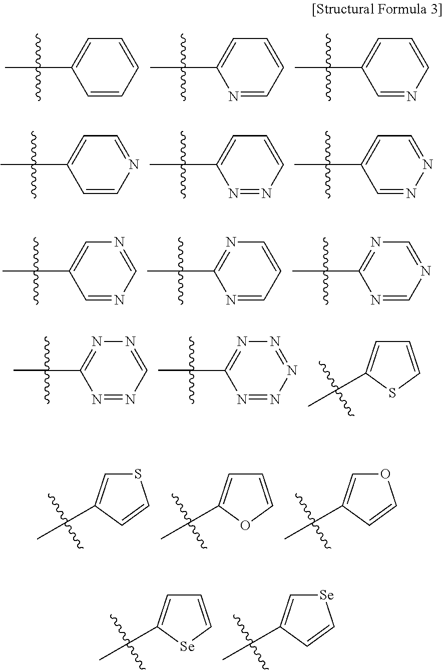

The above Structural Formula 3 may be substituted with any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

In addition, the conductive organic semiconductor compound represented by the above Chemical Formula 1 may be a conductive organic semiconductor compound represented by the following Chemical Formula III:

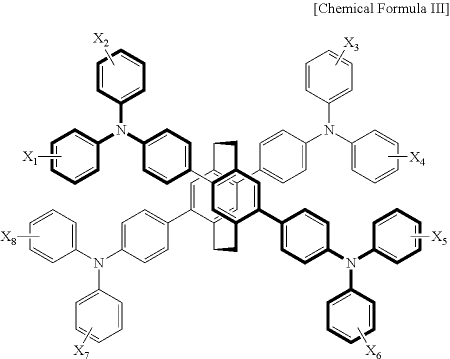

In Chemical Formula III,

X₁, X₂, X₃, X₄, X₅, X₆, X₇ and X₈ are the same or different, and each is independently selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

The conductive organic semiconductor compound represented by the above Chemical Formula II may be a conductive organic semiconductor compound represented by the following Chemical Formula IV:

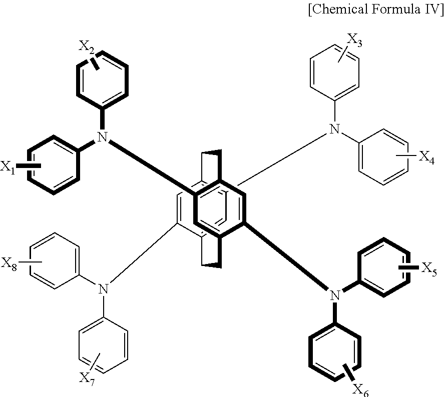

In Chemical Formula IV,

X₁, X₂, X₃, X₄, X₅, X₆, X₇ and X₈ are the same or different, and each independently represents any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

The conductive organic semiconductor compound may have an electron mobility of 1×10⁻⁶ cm²/V·s or higher and a band gap of 1.0-4.0 eV.

More particularly, when the light is input to the organic-inorganic hybrid photoelectric conversion device according to the present disclosure, the incident light reaches the light absorbing material and is absorbed therein. In addition, in each of the electron-hole pairs generated therefrom, electrons move from the hole transport layer 140 as an electron donor (p-semiconductor) to the electron transport layer 120 as an electron acceptor (n-type semiconductor), thereby forming pairing (charge separation state). In other words, electron acceptance or donation is performed through the photoreaction.

The conductive organic semiconductor compound forming the hole transport layer 140 is a disk-like compound, which is advantageous in that intermolecular connection is good and a controllable bandgap is provided depending on substituents.

Particularly, a nitrogen-containing heteroaryl group containing a nitrogen atom may be used preferably. More preferably, the conductive organic semiconductor compound represented by the above Chemical Formula III may be a conductive organic semiconductor compound represented by the following Chemical Formula V:

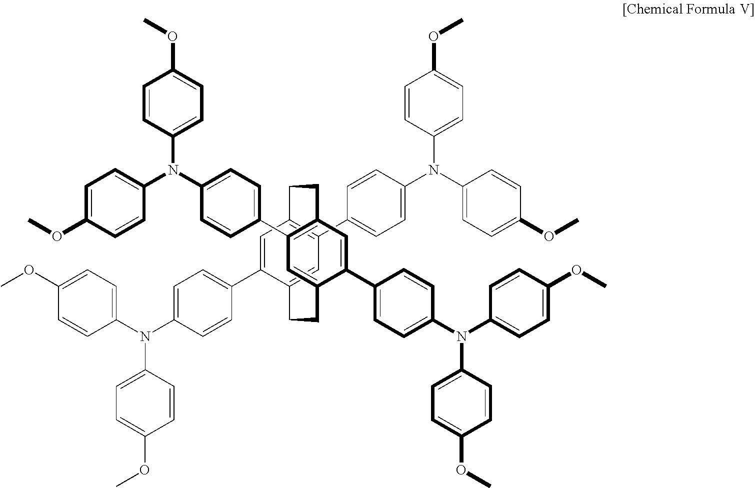

In addition, the conductive organic semiconductor compound represented by the above Chemical Formula IV may be a conductive organic semiconductor compound represented by the following Chemical Formula VI:

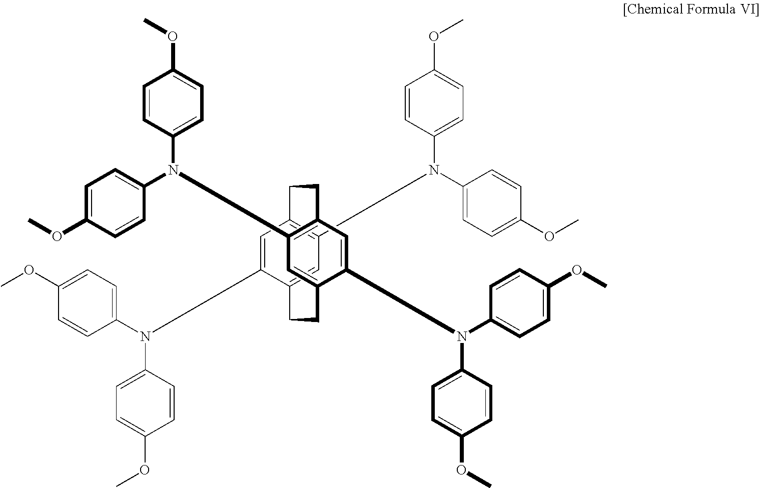

The second electrode 150 formed on the hole transport layer 140 may be any conventional electrode with no particular limitation. Preferably, the second electrode may be any one selected from the group consisting of gold, silver, platinum, palladium, copper, aluminum and a combination thereof. In addition, the second electrode may have an adequate work function depending on the energy level of the highest occupied molecular orbital (HOMO) of the hole transport layer 140.

The hole transport layer 140 may further include a sulfonyl group-containing imide lithium salt. Particularly, when the conductive organic semiconductor compound is a conductive organic semiconductor compound represented by Chemical Formula V or Chemical Formula VI, it is preferred to use such a sulfonyl group-containing imide lithium salt in combination.

The sulfonyl group-containing imide lithium salt may increase the conductivity of the hole transport layer 140 and accelerate the flow of holes, when it is mixed with the conductive organic semiconductor compound. In addition, oxidation caused by the sulfonyl group-containing imide lithium salt further decreases the highest occupied molecular orbital (HOMO) energy level of the conductive organic semiconductor compound, thereby increasing the open circuit voltage of an organic-inorganic hybrid photoelectric conversion device and improving the overall characteristics.

The sulfonyl group-containing imide lithium salt may be at least one selected from the group consisting of lithium bis(trifluoromethanesulfonyl)imide (LITFSI), lithium bis(perfluoroethylsulfonyl) imide (BETI), lithium bis[(perfluoroalkyl)sulfonyl]imide and lithium poly[4,4′-(hexafluoroisopropylidene)diphenoxy]sulfonylimide (LiPHFIPSI). Most preferably, the sulfonyl group-containing imide lithium salt may be lithium bis(trifluoromethanesulfonyl)imide (LITFSI).

In another aspect, the present disclosure provides a method for manufacturing an organic-inorganic hybrid photoelectric conversion device, including the steps of:

I) forming an electron transport layer on a first electrode;

II) forming a light-absorbing material including an organic-inorganic hybrid perovskite compound on the electron transport layer;

III) applying a solution containing a conductive organic semiconductor compound represented by the above Chemical Formula I or Chemical Formula II onto the light-absorbing material, followed by drying, to form a hole transport layer; and

IV) forming a second electrode on the hole transport layer.

More particularly, first, the electron transport layer is formed on the top of the first electrode. Herein, the electron transport layer may be formed by applying a solution containing an n-type semiconductor compound or metal oxide particles, followed by heat treatment.

The solution containing the metal oxide particles or n-type semiconductor compound may be applied through any one process selected from the group consisting of screen printing, spin coating, bar coating, gravure coating, blade coating and roll coating.

Since the electron transport layer has a porous structure, it has an increased contact surface with the light absorbing material formed on the porous structured electron transport layer, thereby further improving photoelectric conversion efficiency. Particularly, when the electron transport layer uses metal oxide particles, it is possible to obtain a larger specific surface area compared to the n-type semiconductor compound.

The metal oxide particles may be any conventional metal oxide particles with no particular limitation. Preferably, the metal oxide particles may be at least one type of particles selected from the group consisting of Ti oxide, In oxide, Zn oxide, Sn oxide, W oxide, Nb oxide, Mo oxide, Mg oxide, Zr oxide, Sr oxide, Yr oxide, La oxide, V oxide, Al oxide, Sc oxide, Sm oxide, ga oxide, SrTi oxide and a combination thereof.

In addition, any conventional n-type semiconductor compound may be used as the n-type semiconductor compound with no particular limitation. For example, the n-type semiconductor compound may include fullerene, octaazaporpyrin, polymeric compounds having aromatic carboxylic anhydride or imide compound as a skeleton, or the like. It is most preferable to use a fullerene derivative having improved solubility.

In other words, since the specific surface area and porous structure of the electron transport layer are important factors affecting the contact area with the light absorbing material, it is preferred to control them effectively. For this, the heat treatment is carried out preferably at 200-500° C. in the air.

Herein, the electron transport layer may be provided to have a thickness of 0.1-5 μm.

Before forming the electron transport layer, the method may further include a step of forming a metal oxide thin film between the first electrode and the electron transport layer. To form the metal oxide thin film, any chemical or physical deposition process used conventionally in semiconductor fabrication processes may be carried out.

In the metal oxide thin film, any conventional metal oxide may be used with no particular limitation. Preferably, the metal oxide may be at least one selected from the group consisting of Ti oxide, In oxide, Zn oxide, Sn oxide, W oxide, Nb oxide, Mo oxide, Mg oxide, Zr oxide, Sr oxide, Yr oxide, La oxide, V oxide, Al oxide, Sc oxide, Sm oxide, ga oxide, SrTi oxide and a combination thereof. More preferably, the metal oxide may be Ti oxide.

Then, the step of forming a light absorbing material (Step II) may be carried out by a simple process including applying and drying a solution containing an organic-inorganic perovskite compound.

Herein, most preferably, the organic-inorganic perovskite compound may be an organic-inorganic perovskite compound represented by the formula of RMX₃. Herein, M may be Pt⁺ or Sn⁺, X may be any one selected from the halogen anions including F⁻, Cl⁻, Br and I⁻, and R may be any one selected from the cations including CH₃NH₃⁺, C₂H₅NH₃⁺, Cs⁺ and HC(NH₂)NH₂⁺.

The step of forming a hole transport layer may be carried out by applying a solution containing a conductive organic semiconductor compound represented by the following Chemical Formula 1 or Chemical Formula II onto the light absorbing material. Herein, the hole transport layer may have a thickness of 30-500 nm.

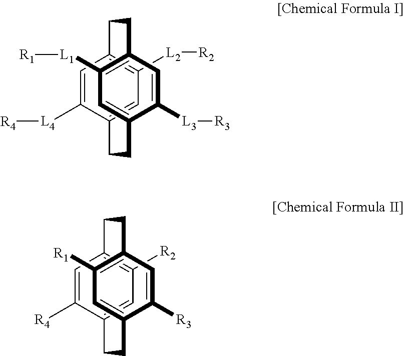

In Chemical Formula I or Chemical Formula II,

L₁, L₂, L₃ and L₄ are the same or different, and each independently represents any one selected from the group consisting of a substituted or non-substituted C5-C50 aryl group and a substituted or non-substituted C2-C50 heteroaryl group containing at least one of S, N, O, P and Si; and

R₁, R₂, R₃ and R₄ are the same or different, and each independently represents any one selected from the following Structural Formula 1:

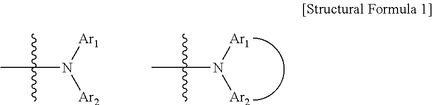

wherein Ar₁ and Ar₂ are the same or different, and each independently represents any one selected from the group consisting of a substituted or non-substituted C5-C50 aryl group and a substituted or non-substituted C2-C50 heteroaryl group containing at least one of S, N, O, P and Si; and

Ar₁ and Ar₂ may be linked to each other through a bonding.

Additionally, in the above Chemical Formula I or Chemical Formula II, each of L₁, L₂, L₃ and L₄ may be any one selected from the following Structural Formula 2:

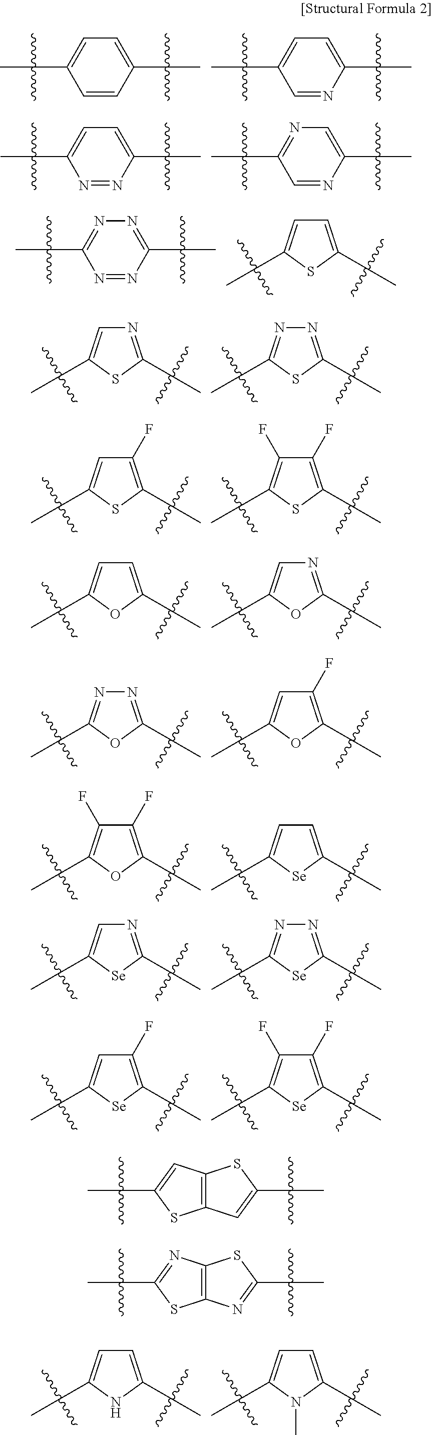

Further, in the above Chemical Formula I or Chemical Formula II, each of Ar₁ and Ar₂ may be any one selected from the following Structural Formula 3:

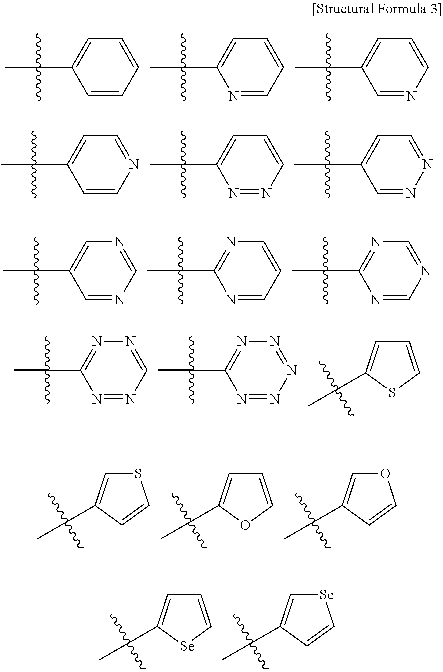

The above Structural Formula 3 may be substituted with any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

In step III), a solution containing at least one conductive organic semiconductor compound selected from the conductive organic semiconductor compounds represented by the above Chemical Formula I or Chemical Formula II may be formed through any one process selected from the group consisting of vacuum deposition, screen printing, printing, spin coating, dipping and ink spraying, followed by applying and drying the solution on the light absorbing material to form a hole transport layer.

In addition, in step III), the solution containing a conductive organic semiconductor compound represented by the above Chemical Formula I or Chemical Formula II may further include a sulfonyl group-containing imide lithium salt.

Particularly, when the conductive organic semiconductor compound is a conductive organic semiconductor compound represented by Chemical Formula V or Chemical Formula VI, it is preferred to use such a sulfonyl group-containing imide lithium salt in combination.

The sulfonyl group-containing imide lithium salt may increase the conductivity of the hole transport layer and accelerate the flow of holes, when it is mixed with the conductive organic semiconductor compound. In addition, oxidation caused by the sulfonyl group-containing imide lithium salt further decreases the highest occupied molecular orbital (HOMO) energy level of the conductive organic semiconductor compound, thereby increasing the open circuit voltage of an organic-inorganic hybrid photoelectric conversion device and improving the overall characteristics.

The sulfonyl group-containing imide lithium salt may be at least one selected from the group consisting of lithium bis(trifluoromethanesulfonyl)imide (LITFSI), lithium bis(perfluoroethylsulfonyl) imide (BETI), lithium bis[(perfluoroalkyl)sulfonyl]imide and lithium poly[4,4′-(hexafluoroisopropylidene)diphenoxy]sulfonylimide (LiPHFIPSI). Most preferably, the sulfonyl group-containing imide lithium salt may be lithium bis(trifluoromethanesulfonyl)imide (LITFSI).

In step III), the solution containing the conductive organic semiconductor compound may further include a solvent. There is no particular limitation in the solvent, as long as it does not chemically react with the light absorbing material and the material of electron transport layer. Preferably, the solvent may be at least one selected from the group consisting of toluene, dimethylformamide, methanol, hexane, tri(ortho-tolyl)phosphine, chlorobenzene, ethylene acetate, tetrahydrofuran and N-methylpyrrodinone.

In step III), the drying may be carried out at 60-200° C. for 2-60 hours, preferably at 80-140° C. for 8-48 hours. When the drying is carried out at lower than 60° C. for less than 2 hours, the solution cannot be dried sufficiently and the light absorbing material is exposed to the solvent and degraded. When the drying is carried out at higher than 200° C. for more than 60 hours, the resultant hole transport layer may be cracked due to such excessive drying. Thus, it is preferred to carry out drying under the above-defined condition.

Finally, the second electrode is formed on the hole transport layer. The second electrode may be formed on the hole transport layer through a physical vapor deposition or chemical vapor deposition process.

In still another aspect, the present disclosure provides a method for preparing the conductive organic semiconductor compound according to the present disclosure. The solution containing the conductive organic semiconductor compound may also be prepared through the following steps.

The method uses a simple process and the conductive organic semiconductor compound is prepared with ease. Thus, the conductive organic semiconductor compound obtained by the method is inexpensive and allows mass production at low cost. Therefore, when applying the conductive organic semiconductor compound according to the present disclosure to organic-inorganic hybrid photoelectric conversion devices, it is possible to reduce the cost.

i) dissolving a compound represented by the following Chemical Formula VII and a compound represented by the following Chemical Formula VIII into a solvent to provide a mixed solution; and

ii) adding a palladium catalyst to the mixed solution and carrying out a reaction of the compound represented by the following Chemical Formula VII with the compound represented by the following Chemical Formula VIII to obtain a conductive organic semiconductor compound represented by the following Chemical Formula I:

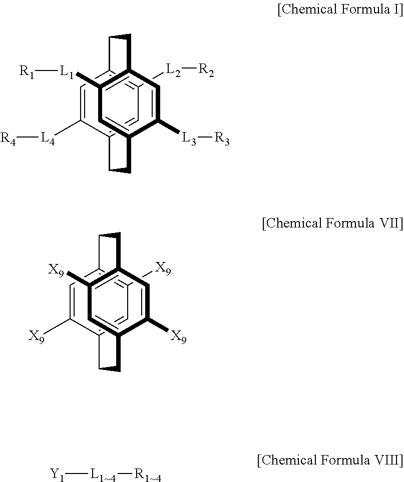

In Chemical Formula VII, X₉ represents a halide such as Cl, Br or I.

In Chemical Formula I and Chemical Formula VIII,

Y₁ is any one selected from BO₂R₅R₆ and SnR₇R₈R₉, R₅, R₆, R₇, R₈ and R₉ are the same or different, and each represents hydrogen or a C1-C8 alkyl group, wherein R₅ and R₆ are linked to each other through a bonding.

L₁₋₄ (L₁, L₂, L₃ and L₄) are the same or different, and each is independently selected from the group consisting of a substituted or non-substituted C5-C50 aryl group and substituted or non-substituted C2-C50 heteroaryl group containing at least one of S, N, O, P and Si.

Each of R₁₋₄ (R₁, R₂, R₃ and R₄) may be any one selected from the following Structural Formula 1:

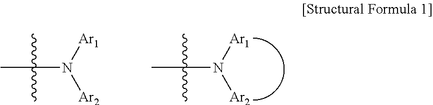

wherein Ar₁ and Ar₂ are the same or different, and each independently represents a substituted or non-substituted C5-C50 aryl group and a substituted or non-substituted C2-C50 heteroaryl group containing at least one of S, N, O, P and Si; and

Ar₁ and Ar₂ may be linked to each other through a bonding.

In the above Chemical Formula VIII, each of L₁₋₄ (L₁, L₂, L₃ and L₄) may be any one selected from the following Structural Formula 2:

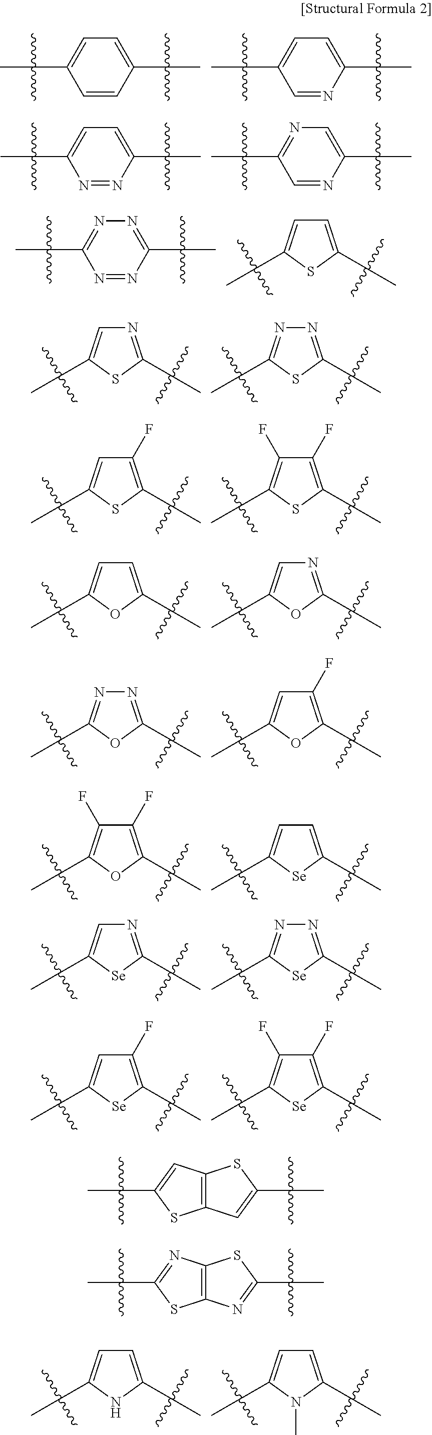

In Structural Formula 1, Ar₁ and Ar₂ are the same or different and each may be any one selected from the following Structural Formula 3:

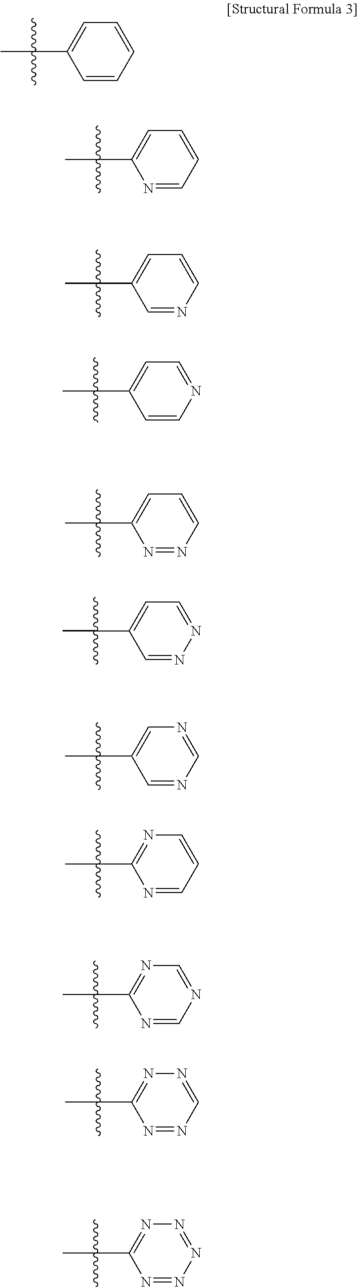

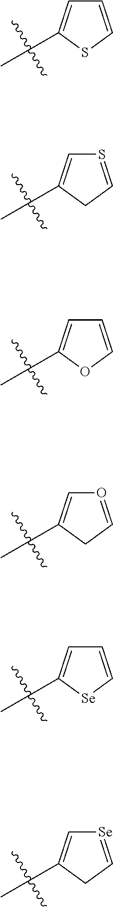

The above Structural Formula 3 may be substituted with any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

Preferably, the mixing ratio of the compound represented by Chemical Formula VII to the compound represented by Chemical Formula VIII may be 1:0.5-10 on the molar basis.

The solvent is not particularly limited. Preferably, the solvent may be at least one selected from the group consisting of toluene, dimethylformamide, methanol, hexane, tri(ortho-tolyl)phosphine, chlorobenzene, ethylene acetate, tetrahydrofuran and N-methylpyrrolidinone.

The reaction may be carried out at 60-200° C. for 2-60 hours, preferably at 80-140° C. for 8-48 hours. When the reaction is carried out at lower than 60° C. for less than 2 hours, it is not possible to accomplish synthesis sufficiently. When the reaction is carried out at higher than 200° C. for more than 60 hours, impurities are generated, resulting in a decrease in yield. Thus, it is preferred to carry out the reaction under the above-defined condition.

In yet another aspect, the present provides a method for preparing the conductive organic semiconductor compound according to the present disclosure. The solution containing the conductive organic semiconductor may also be prepared through the following steps.

The method uses a simple process and the conductive organic semiconductor compound is prepared with ease. Thus, the conductive organic semiconductor compound obtained by the method is inexpensive and allows mass production at low cost. Therefore, when applying the conductive organic semiconductor compound according to the present disclosure to organic-inorganic hybrid photoelectric conversion devices, it is possible to reduce the cost.

i) dissolving a compound represented by the following Chemical Formula VII and a compound represented by the following Chemical Formula IX into a solvent to provide a mixed solution; and

ii) adding a palladium catalyst to the mixed solution and carrying out a reaction of the compound represented by the following Chemical Formula VII with the compound represented by the following Chemical Formula IX to obtain a conductive organic semiconductor compound represented by the following Chemical Formula II:

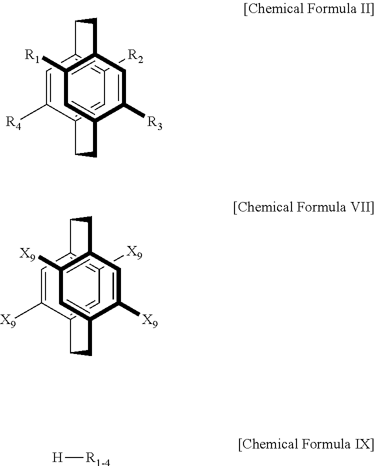

In Chemical Formula VII, X₉ represents a halide such as Cl, Br or I.

In Chemical Formula II and Chemical Formula IX,

R₁₋₄ may be any one selected from the following Structural Formula 1:

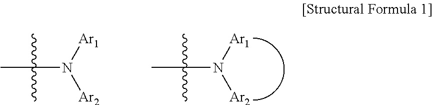

wherein Ar₁ and Ar₂ are the same or different, and each independently represents any one selected from the group consisting of a substituted or non-substituted C5-C50 aryl group and a substituted or non-substituted C2-C50 heteroaryl group containing at least one of S, N, O, P and Si; and

Ar₁ and Ar₂ may be linked to each other through a bonding.

In Structural Formula 1, Ar₁ and Ar₂ are the same or different and each may be any one selected from the following Structural Formula 3:

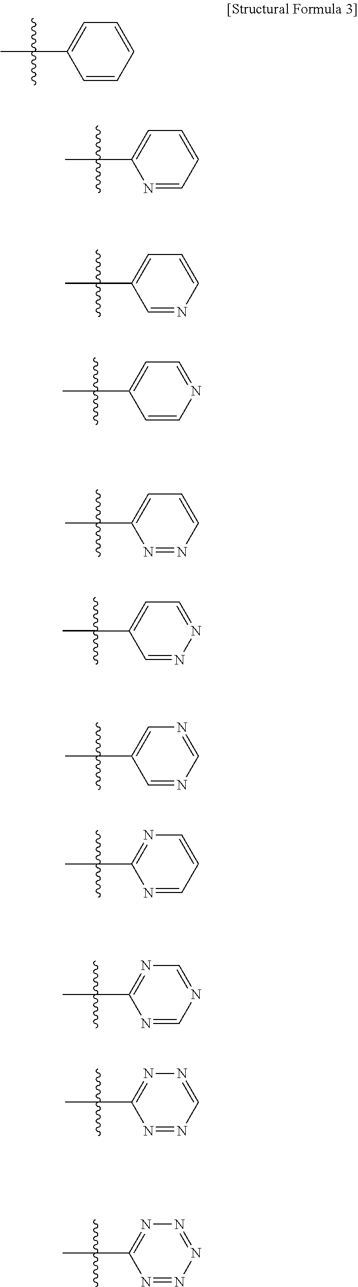

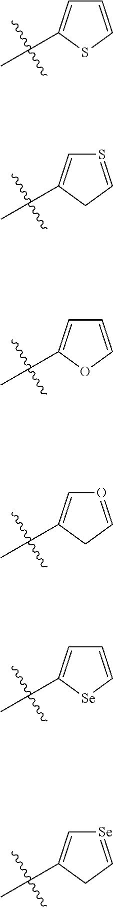

The above Structural Formula 3 may be substituted with any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

The mixing ratio of the compound represented by Chemical Formula VII to the compound represented by Chemical Formula IX may be 1:0.5-10 on the molar basis.

The solvent is not particularly limited. Preferably, the solvent may be at least one selected from the group consisting of toluene, dimethylformamide, methanol, hexane, tri(ortho-tolyl)phosphine, chlorobenzene, ethylene acetate, tetrahydrofuran and N-methylpyrrolidinone.

The reaction may be carried out at 60-200° C. for 2-60 hours, preferably at 80-140° C. for 8-48 hours. When the reaction is carried out at lower than 60° C. for less than 2 hours, it is not possible to accomplish synthesis sufficiently. When the reaction is carried out at higher than 200° C. for more than 60 hours, impurities are generated, resulting in a decrease in yield. Thus, it is preferred to carry out the reaction under the above-defined condition.

The examples and experiments will now be described. The following examples and experiments are for illustrative purposes only and not intended to limit the scope of this disclosure. In addition, it will be apparent to those skilled in the art that various changes and modifications may be made without departing from the spirit and scope of the disclosure as defined in the following claims.

### Preparation Example 1

### Synthesis of Conductive Organic Semiconductor Compound According to the Present Disclosure

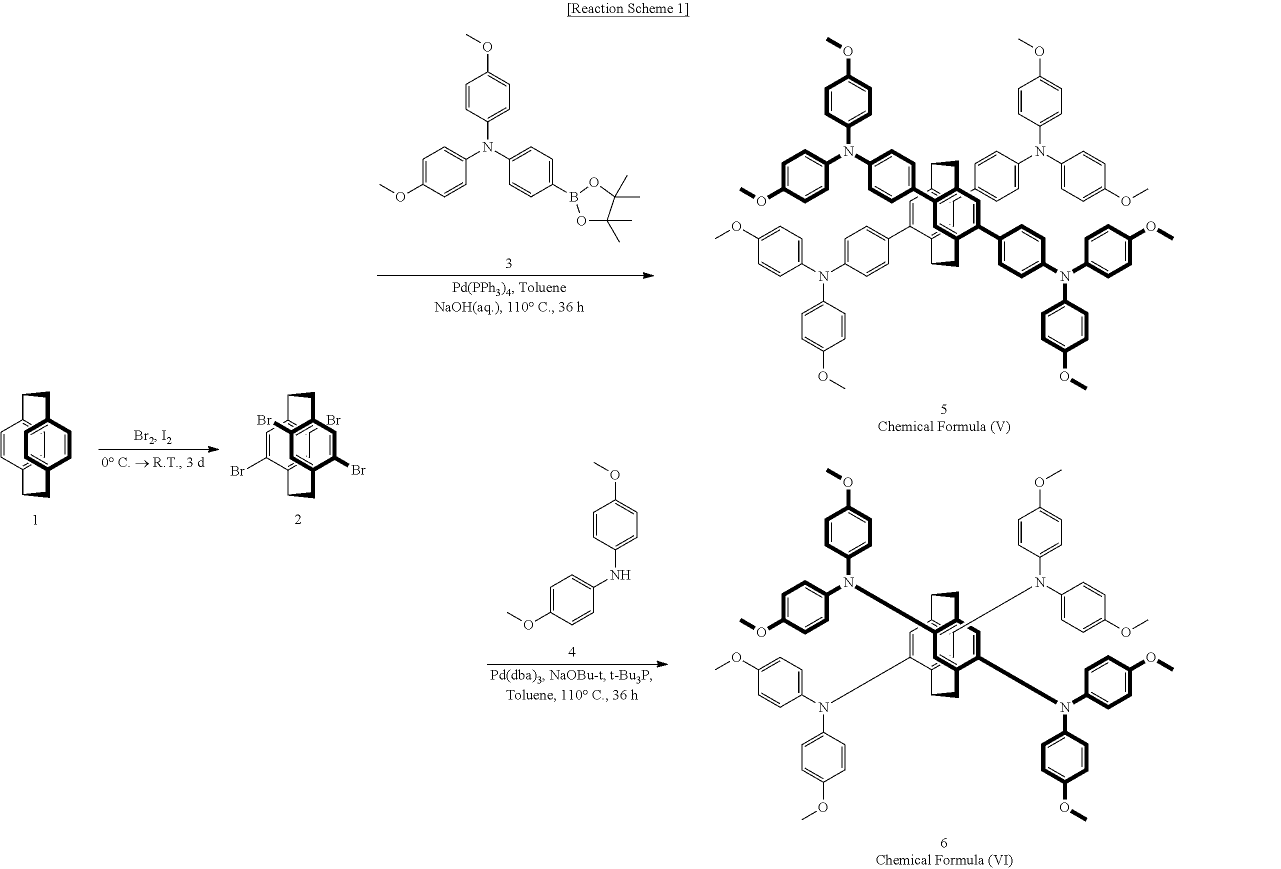

The compound represented by Chemical Formula 3 as shown in the above Reaction Scheme 1 is prepared according to the same manner as reported in Amthor, S.; Lambert, C. J. Phys. Chem. A 2006, 110, 1177-1189.

### Synthesis Example 1

### Synthesis of 4,7,12,15-tetrabromo[2,2]paracyclophene (Compound 2)

To a 100 mL flask having a magnetic agitation bar, iodine (78.7 mg, 0.314 mmol) is introduced and cooled to 0° C. by using iced water, and then bromine (48.15 g, 301.3 mmol) is further introduced thereto to provide a first mixed solution. At 0° C., a compound represented by Chemical Formula 1 is added to the first mixed solution in portions and a reaction is carried out between them at room temperature for 8 days to provide a second mixed solution. Then, aqueous solution of sodium bisulfite and sodium hydroxide is added to the second mixed solution to quench and neutralize the reaction, followed by extraction with chloroform (200 mL) three times, thereby providing an extract solution. Finally, the organic layer formed in the extract solution is dried with magnesium sulfate, the solvent is removed through a rotary evaporator, and the resultant product is separated by column chromatography (eluent: hexane) to obtain a compound represented by Chemical formula 2.

¹H NMR (400 MHz, CDCl₃) δ 2.92-3.05 (m, 4H), 3.18-3.30 (m, 4H), 7.17 (s, 4H).

### Synthesis Example 2

### Synthesis of 4,7,12,15-tetrakis-{4-amino-[N,N-di-(4-methoxyphenyl)]-phenyl}-[2,2]paracyclophene (Chemical Formula V)

To a 25 mL flask having a magnetic agitation bar, the compound obtained from Synthesis Example 1 (Chemical Formula 2; 203.6 mg, 0.389 mmol), a compound represented by Chemical Formula 3 (804.5 mg, 1.865 mmol) and tetrakis(triphenylphosphine)palladium(0) (Pd(PPh₃)₄) (89.8 mg, 77.7 μmol) are introduced to provide a first mixed solution. To the first mixed solution, toluene (6 mL) degassed by argon bubbling, aqueous sodium hydroxide solution (2 mL, 2M) and aliquat 336 (two drops) are added to provide a second mixed solution. The second mixed solution is allowed to react at 110° C. for about 36 hours, cooled to room temperature, and then diluted with chloroform (100 mL), followed by washing with water and saline three times, to provide an extract solution. Finally, the organic layer formed in the extract solution is dried with magnesium sulfate, the solvent is removed through a rotary evaporator, and the resultant product is separated by column chromatography (eluent: ethyl acetate:hexane=1:2) to obtain a compound represented by Chemical formula V (4,7,12,15-tetrakis-{4-amino-[N,N-di-(4-methoxyphenyl)]-phenyl}-[2,2]paracyclophene).

¹H NMR (400 MHz, CD₂Cl₂) δ 2.65-2.90 (m, 4H), 3.35-3.60 (m, 4H), 3.79 (s, 24H), 6.73 (s, 4H), 6.83 (d, 16H), 6.90 (d, 8H), 7.06 (d, 16H), 7.18 (d, 8H).

### Synthesis Example 3

### Synthesis of 4,7,12,15-tetrakis-{N,N-di-(4-methoxyphenyl)amine}-[2,2]paracyclophene (Chemical Formula VI)

To a 25 mL flask having a magnetic agitation bar, the compound obtained from Synthesis Example 1 (Chemical Formula 2; 201.1 mg, 0.384 mmol), a compound represented by Chemical Formula 4 (422.5 mg, 1.843 mmol), sodium tert-butoxide (221.4 mg, 2.304 mmol) and tris(dibenzylideneacetone)dipalladium(0)-chloroform adduct (Pd2(dba)3 CHCl₃) (79.5 mg, 76.8 μmol) are introduced to provide a first mixed solution. To the first mixed solution, degassed toluene (8 mL) and tri-tert-butylphosphine (23.3 mg, 0.115 mmol) are added to provide a second mixed solution. The second mixed solution is allowed to react at 110° C. for about 36 hours, cooled to room temperature, and then diluted with chloroform (100 mL), followed by washing with water and saline three times, to provide an extract solution. Finally, the organic layer formed in the extract solution is dried with magnesium sulfate, the solvent is removed through a rotary evaporator, and the resultant product is separated by column chromatography (eluent: ethyl acetate:hexane=1:2) to obtain a compound represented by Chemical formula VI (4,7,12,15-tetrakis-{N,N-di-(4-methoxyphenyl)amine}-[2,2]paracyclophene).

### Example 1

### Manufacture of Organic-Inorganic Hybrid Photoelectric Conversion Device

A transparent conductive film of fluorine doped tin oxide (FTO) is formed on a glass substrate and patterned into a stripe form by using conventional photolithography and HCl etching, thereby forming a transparent first electrode.

Next, a metal oxide paste in which titanium dioxide (TiO₂) nanoparticles having an average particle diameter of 25 nm (10-40 nm) are mixed with ethanol is coated onto the first electrode through a spin coating process, and then the resultant coating is heat treated at 500° C. for 60 minutes to form an electron transport layer having a thickness of 200 nm.

To form a light absorbing material on the electron transport layer, red diiodide (PbI₂) is dissolved into dimethyl formamide (DMF) and agitated at 70° C. for 12 hours to provide a first mixed solution. Methylammonium iodide (CH₃NH₃I) is dissolved into isopropanol to provide a second mixed solution. Then, the first mixed solution is applied onto the electron transport layer through spin coating under 6500 rpm for 60 seconds, and then the second mixed solution is further applied thereto under 1000 rpm for 10 seconds, thereby forming a perovskite light absorbing material.

Then, the compound obtained from Preparation Example 1 (Chemical Formula V: 4,7,12,15-tetrakis-{4-amino-[N,N-di-(4-methoxyphenyl)]-phenyl}-[2,2]paracyclophene, conductive organic semiconductor compound) is dissolved into chlorobenzene to provide a mixed solution. After that, 10 parts by weight of lithium bis(trifluoromethanesulfonyl)imide and 53 parts by weight of 4-tert-butyl pyridine, based on 100 parts by weight of the compound obtained from Preparation Example 1 and contained in the mixed solution, are added to the mixed solution. Then, the resultant mixed solution is applied onto the perovskite light absorbing material through spin coating under 2,500 rpm for 20 seconds, thereby forming a hole transport layer.

Finally, gold is vacuum deposited on the hole transport layer by using a thermal evaporator under high vacuum (5×10⁻⁶ torr or less) to form a second electrode.

In this manner, an organic-inorganic hybrid photoelectric conversion device having an area of 2.5 cm×2.5 cm is obtained.

### Example 2

### Manufacture of Organic-Inorganic Hybrid Photoelectric Conversion Device

An organic-inorganic hybrid photoelectric conversion device is obtained in the same manner as Example 1, except that the spin coating for forming a hole transport layer is carried out under 3000 rpm for 20 seconds.

### Example 3

An organic-inorganic hybrid photoelectric conversion device is obtained in the same manner as Example 1, except that the compound (Chemical Formula VI) obtained from Preparation Example 2 is used for the hole transport layer.

### Comparative Example 1

An organic-inorganic hybrid photoelectric conversion device is obtained in the same manner as Example 1, except that 2,7-bis(N,N-(4-dimethoxyphenyl)amino)-9,9′-spirobifluorene (Spiro-MeOTPD) is used for the hole transport layer.

### Comparative Example 2

An organic-inorganic hybrid photoelectric conversion device is obtained in the same manner as Example 1, except that 2,2′,7,7′-tetrakis(N,N-p-dimethoxyphenylamino)-9,9′-spirobifluorene (Spiro-OMeTAD) is used for the hole transport layer.

### Comparative Example 3

An organic-inorganic hybrid photoelectric conversion device is obtained in the same manner as Example 1, except that 2,2′-bis(N,N-(4-dimethoxyphenyl)amino)-9,9′-spirobifluorene (2,2′-MeO-spiro-TPD) is used for the hole transport layer.

### Comparative Example 4

An organic-inorganic hybrid photoelectric conversion device is obtained in the same manner as Example 1, except that the hole transport layer is excluded.

### Test Example 1

### Characterization of Compound Obtained from Preparation Example 1 (Chemical Formula V)

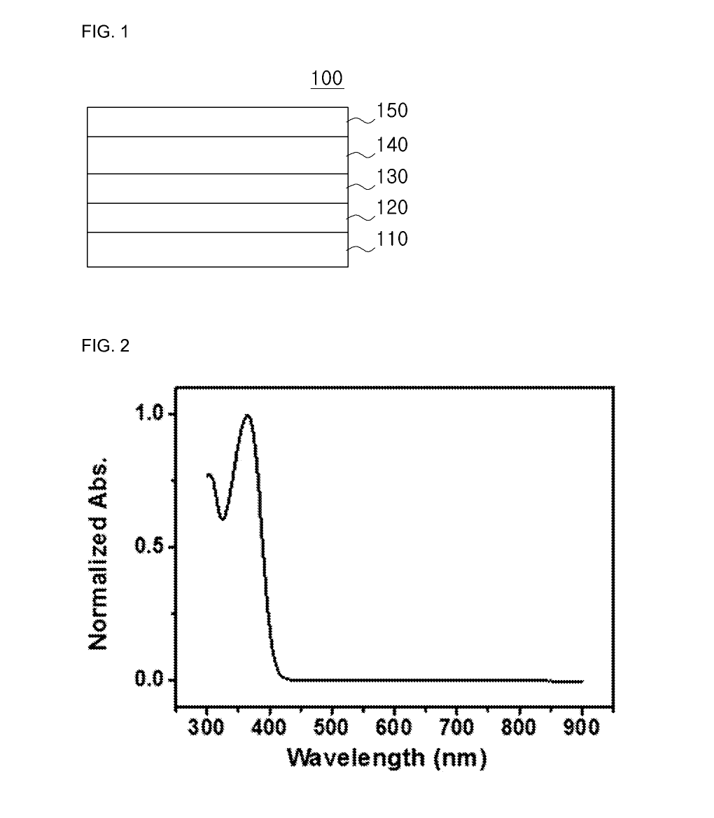

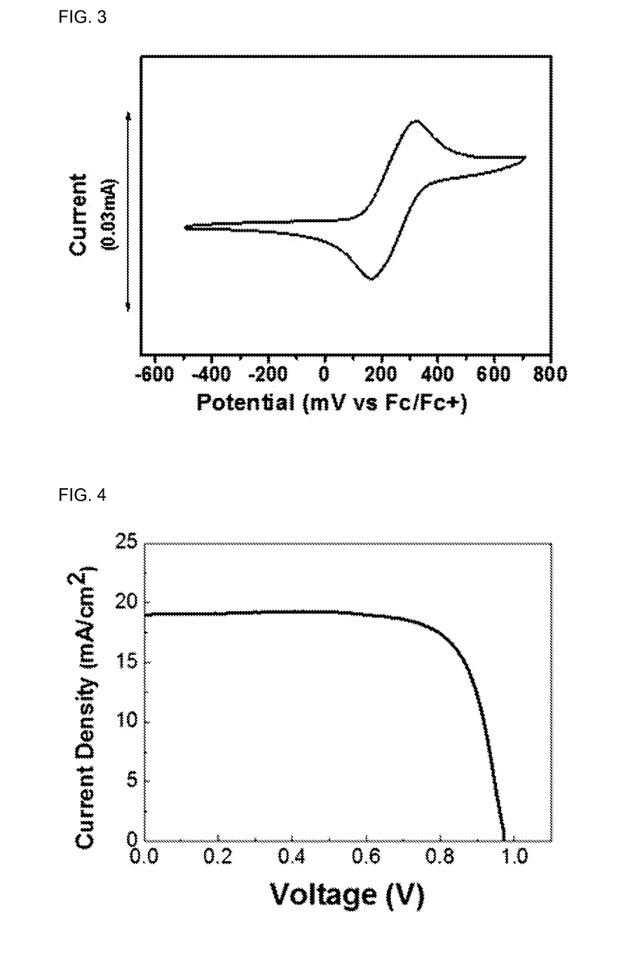

FIG. 2 is an absorbance graph of 4,7,12,15-tetrakis-{4-amino-[N,N-di-(4-methoxyphenyl)]-phenyl}-[2,2]paracyclophene (Chemical Formula V) obtained from Synthesis Example 2, and FIG. 3 is a cyclic voltammetry graph of 4,7,12,15-tetrakis-{4-amino-[N,N-di-(4-methoxyphenyl)]-phenyl}-[2,2]para cyclophene (Chemical Formula V) obtained from Synthesis Example 2.

Based on the absorbance graph and cyclic voltammetry graph of FIG. 2 and FIG. 3, respectively, the values of maximum absorbance (λₘₐₓ), onset absorbance (λₒₙₛₑₜ), optical band gap (E_{g, opt}) and highest occupied molecular orbital (HOMO) in solution are calculated.

In addition, the values of maximum absorbance (λₘₐₓ), onset absorbance (λₒₙₛₑₜ), optical band gap (E_{g, opt}) and highest occupied molecular orbital (HOMO) for the compound obtained from Preparation Example 2 (Chemical Formula V) in solution are calculated. The results are shown in the following Table 1.

TABLE 1

| | | | | Highest |
|---|---|---|---|---|
| | | | | occupied |
| | Maximum | Onset | Optical | molecular |
| | absorbance | absorbance | band gap | orbital |
| | (λₘₐₓ) | (λₒₙₛₑₜ) | (E_{g,opt}) | (HOMO) |
| Compound of | 365 nm | 404 nm | 3.07 eV | −5.04 eV |
| Preparation | | | | |
| Example 1 | | | | |
| (Chemical | | | | |
| Formula V) | | | | |

As can be seen from the above results, the conductive organic compound is favorable to acquisition of a high open circuit voltage in a solar cell at a low level of highest occupied molecular orbital (HOMO), and interrupts electrons from being transported in a reverse direction at a large energy band gap to prevent a loss in electric current.

In addition, the compound obtained from Preparation Example 1 is prepared through a smaller number of steps at lower cost, as compared to the hole transport material used in the photoelectric conversion devices according to Comparative Examples 1-3. Thus, it can be seen that the compound has excellent characteristics, such as a low level of highest occupied molecular orbital, although it has higher cost efficiency.

### Test Example 2

### Characterization of Organic-Inorganic Hybrid Photoelectric Conversion Device Obtained from Example 1

FIG. 4 is a graph illustrating the results of determination of current-voltage characteristics of the organic-inorganic hybrid photoelectric conversion device obtained from Example 1.

Based on the graph of FIG. 4, the values of open circuit voltage, photoelectric current density, energy conversion efficiency and fill factor are calculated. The results are shown in the following Table 2.

TABLE 2

| | Open circuit | Current | Fill | Energy conversion |
|---|---|---|---|---|
| | voltage | density | factor | efficiency |
| | (V) | (mA/cm²) | (%) | (%) |
| Example 1 | 0.971 | 19.01 | 75.55 | 13.95 |

As can be seen from the above results, the perovskite solar cell using a conductive organic compound according to the present disclosure has a high open circuit voltage, current density and fill factor, and thus shows high efficiency.

### Test Example 3

To compare the characteristics of the organic-inorganic hybrid photoelectric conversion device according to the present disclosure with those of the conventional organic-inorganic hybrid photoelectric conversion device more precisely, the characteristics of the organic-inorganic hybrid photoelectric conversion devices according to Examples 2 and 3 and those of the organic-inorganic hybrid photoelectric conversion devices obtained from Comparative Examples 1-4 are determined. The results are shown in the following Table 3.

TABLE 3

| | Open circuit | Current | Fill | Energy conversion |
|---|---|---|---|---|
| | voltage | density | factor | efficiency |
| | (V) | (mA/cm²) | (%) | (%) |
| Ex. 2 | 0.997 | 19.68 | 71.65 | 14.0 |
| Ex. 3 | 0.984 | 19.15 | 69.88 | 13.2 |
| Comp. Ex. 1 | 0.932 | 16.84 | 69.64 | 10.9 |
| Comp. Ex. 2 | 0.992 | 20.00 | 70.00 | 13.88 |
| Comp. Ex. 3 | 0.931 | 9.90 | 39.63 | 3.7 |
| Comp. Ex. 4 | 0.513 | 7.60 | 34.21 | 1.3 |

As can be seen from Table 3, the organic-inorganic hybrid photoelectric conversion devices according to Examples 2 and 3 have significantly higher characteristics compared to the organic-inorganic hybrid photoelectric conversion devices obtained from Comparative Examples 1-4. Particularly, in the case of the organic-inorganic photoelectric conversion device obtained from Comparative Example 4, it uses no hole transport layer, and thus provides the organic-inorganic photoelectric conversion device with significantly lower overall characteristics.

In general, when a light absorbing material containing an organic-inorganic perovskite compound is exposed to the air or liquid, it is degraded with ease. Moreover, such a light absorbing material is water soluble, and thus easily subjected to leakage, resulting in poor lifespan.

However, when using the conductive organic semiconductor device according to the present disclosure for a hole transport layer, it has a conjugated surface by virtue of π-π interaction thereof and highly dense arrangement. Thus, the conductive organic semiconductor compound is bound well with the organic-inorganic perovskite compound organically and it isolates the light absorbing material from the exterior effectively, while not reacting with the organic-inorganic perovskite compound. As a result, the organic-inorganic hybrid photoelectric conversion device using the conductive organic semiconductor compound has excellent characteristics.

Meanwhile, although the organic-inorganic hybrid photoelectric conversion device according to Comparative Example 2 is similar to the organic-inorganic hybrid photoelectric conversion devices according to Examples 2 and 3 in terms of quality, the organic-inorganic hybrid photoelectric conversion devices according to Examples 2 and 3 prevent the leakage of a light absorbing material to a higher degree as compared to the organic-inorganic hybrid photoelectric conversion device according to Comparative Example 2. As a result, the organic-inorganic hybrid photoelectric conversion devices according to Examples 2 and 3 have significantly improved lifespan characteristics.

In addition, it can be seen that although the conductive organic semiconductor compound in the organic-inorganic hybrid photoelectric conversion devices according to Examples 2 and 3 is prepared through a smaller number of steps within a shorter time and has higher cost efficiency compared to the hole transport material used in the organic-inorganic hybrid photoelectric conversion device according to Comparative Example 2, the conductive organic semiconductor compound shows excellent characteristics.

What is claimed is:

1. An organic-inorganic hybrid photoelectric conversion device, comprising a first electrode, a second electrode opposite to the first electrode, and an electron transport layer, light-absorbing material and a hole transport layer disposed between the first electrode and the second electrode,
wherein the light-absorbing material comprises an organic-inorganic hybrid perovskite compound, and
the hole transport layer comprises a conductive organic semiconductor compound represented by the following Chemical Formula I or Formula II: 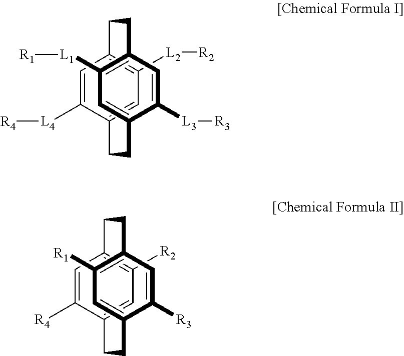
In Chemical Formula I or Chemical Formula II,
L₁, L₂, L₃ and L₄ are the same or different, and each independently represents any one selected from the group consisting of a substituted or non-substituted C5-C50 aryl group and a substituted or non-substituted C2-C50 heteroaryl group containing at least one of S, N, O, P and Si; and
R₁, R₂, R₃ and R₄ are the same or different, and each independently represents any one selected from the following Structural Formula 1: 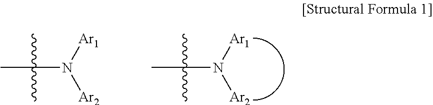
wherein Ar₁ and Ar₂ are the same or different, and each independently represents any one selected from the group consisting of a substituted or non-substituted C5-C50 aryl group and a substituted or non-substituted C2-C50 heteroaryl group containing at least one of S, N, O, P and Si; and
Ar₁ and Ar₂ may be linked to each other through a bonding.

2. The organic-inorganic hybrid photoelectric conversion device according to claim 1, wherein each of L₁, L₂, L₃ and L₄ in Structural Formula 1 is any one selected from the following Structural Formula 2:

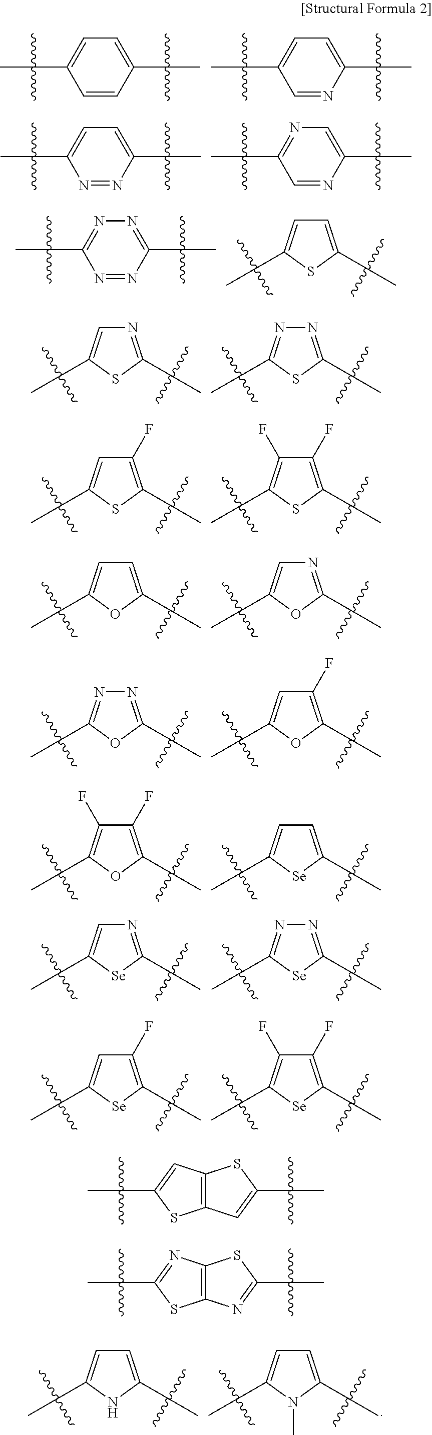

3. The organic-inorganic hybrid photoelectric conversion device according to claim 1, wherein Ar₁ and Ar₂ are the same or different and each is any one selected from the following Structural Formula 3:

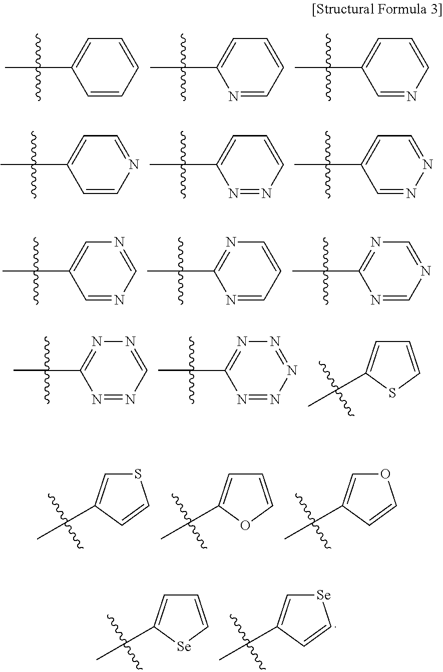

4. The organic-inorganic hybrid photoelectric conversion device according to claim 3, wherein Structural Formula 3 is substituted with any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

5. The organic-inorganic hybrid photoelectric conversion device according to claim 1, wherein the conductive organic semiconductor compound represented by the above Chemical Formula 1 is a conductive organic semiconductor compound represented by the following Chemical Formula III: 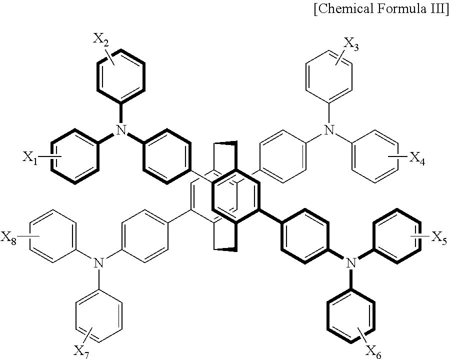
In Chemical Formula III,
X₁, X₂, X₃, X₄, X₅, X₆, X₇ and X₈ are the same or different, and each is independently selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

6. The organic-inorganic hybrid photoelectric conversion device according to claim 1, wherein the conductive organic semiconductor compound represented by the above Chemical Formula II is a conductive organic semiconductor compound represented by the following Chemical Formula IV: 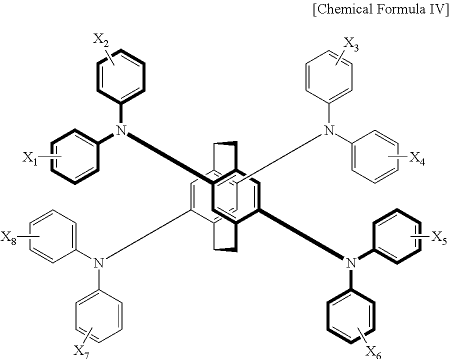
In Chemical Formula IV,
X₁, X₂, X₃, X₄, X₅, X₆, X₇ and X₈ are the same or different, and each independently represents any one selected from the group consisting of: hydrogen, a halogen group, cyano group, nitro group, hydroxyl group, amide group, ester group, ketone group, thioether group, silyl group, substituted or non-substituted C1-C30 alkyl group, substituted or non-substituted C2-C30 alkenyl group, substituted or non-substituted C2-C30 alkynyl group, substituted or non-substituted C2-C50 heteroaryl group containing at least one of S, N, O, P and Si, substituted or non-substituted C3-C30 cycloalkyl group, substituted or non-substituted C3-C30 cycloalkenyl group, substituted or non-substituted C5-C50 aryl group, substituted or non-substituted C1-C30 alkoxy group, substituted or non-substituted C5-C50 aryloxy group, substituted or non-substituted C1-C30 alkylamino group, substituted or non-substituted C6-C30 arylamino group, substituted or non-substituted C1-C30 alkylsilyl group, and a substituted or non-substituted C5-C50 arylsilyl group.

7. The organic-inorganic hybrid photoelectric conversion device according to claim 1, wherein the conductive organic semiconductor compound has an electron mobility of 1×10⁻⁶ cm³/V·s or higher, and a band gap of 1.0-4.0 eV.

8. The organic-inorganic hybrid photoelectric conversion device according to claim 1, wherein the hole transport layer further comprises a sulfonyl group-containing imide lithium salt, and the sulfonyl group-containing imide lithium salt is at least one selected from the group consisting of lithium bis(trifluoromethane sulfonyl)imide (LITFSI), lithium bis(perfluroethylsulfonyl) imide (BETI), lithium bis[(perefluoroalkyl)sulfonyl]imide and lithium poly[4,4′-(hexafluoroisopropylidene)diphenoxy]sulfonyl imide (LiPHFIPSI).
